(19) United States
(12) Patent Application Publication
(10) Pub. No.: US 2015/0235854 A1
(43) Pub. Date: Aug. 20, 2015

(54) Method for Manufacturing Semiconductor Device

(71) Applicant: INSTITUTE OF MICROELECTRONICS, CHINESE ACADEMY OF SCIENCES, Beijing (CN)

(72) Inventors: Haizhou Yin, Poughkeepsie, NY (US); Zhiguo Zhao, Beijing (CN)

(21) Appl. No.: 14/435,261

(22) PCT Filed: Nov. 13, 2012
(86) PCT No.: PCT/CN2012/001535

§ 371 Date: Apr. 13, 2015

(30) Foreign Application Priority Data
Oct. 16, 2012 (CN) 201210393669.2

(51) Int. Cl. H01L 21/28; H01L 29/66

(52) U.S. Cl. CPC H01L 21/28008; H01L 29/66545

(57) ABSTRACT

A method for manufacturing a semiconductor device is disclosed. The method comprises forming a etch stop layer and a dummy gate layer on a substrate; forming a dummy gate pattern by wet etching the dummy gate layer; forming a gate spacer around said dummy gate pattern; removing said dummy gate pattern by wet etching to form a gate trench; and forming a gate stack in the gate trench. In the method for manufacturing a semiconductor device according to the invention, epitaxial monocrystalline thin film is used as the dummy gate and the stop layer for wet etching the dummy gate. As a result, the verticality of the gate profile is improved, erosion of substrate at corner of the bottom is avoided, and therefore performance and reliability of the device is effectively improved.

### CROSS REFERENCE

This application is a National Stage Application of, and claims priority to, PCT Application No. PCT/CN2012/001535, filed on Nov. 13, 2012, entitled “Semiconductor Device Manufacturing Method”, which claims priority to Chinese Application No. 201210393669.2, filed on Oct. 16, 2012. Both the PCT application and the Chinese application are incorporated herein by reference in their entireties.

### FIELD OF THE INVENTION

The present invention relates to a method for manufacturing semiconductor devices, and in particular to a method for manufacturing MOSFETs with improved gate profile.

### BACKGROUND OF THE INVENTION

As the size of semiconductor devices such as MOSFETs keeps scaling down in proportion, the conventional gate stack structure which consists of a gate insulating layer such as silicon oxide and a gate conductive layer such as doped polysilicon is no longer suitable for smaller-size device application. High-k (HK) material can be used to reduce the equivalent oxide thickness (EOT), and metal gate (MG) can be used to effectively adjust gate work function. Hence HK/MG structure has become a mainstream design. Compared to the gate-first technology, the gate-last technology, which includes forming a dummy gate stack, depositing interlayer dielectric layer (ILD), removing the dummy gate stack to generate a gate trench, and depositing a final HK/MG gate stack, become mainstream in HK/MG structure manufacturing since the size of the gate can be controlled more precisely and high-temperature effect (which, for example, during activating dopants in polysilicon or annealing in order to reduce interface defects of high-k material, causes other impurities in the device to migrate) can be avoided.

However, when a dummy gate stack is removed by dry etching such as reactive ion etching (RIE), a trench with tapered side-walls, instead of vertical side-walls, is generally obtained due to the complication of etching technology including the selection of etching terminals, the adjustment of etching rate, and the choice of etching selection ratio, etc. The tapered side-walls can cause problems, such as low filling rate as well as porosity, in a later process for depositing metal material to fill the gate trench. When a dummy gate of polysilicon or amorphous silicon is wet etched with TMAH, vertical side-walls can be obtained. However, over etching may occur at the bottom and the corners of the trench, i.e. corner substrate etching, which increases defects at the surface of the channel region. As a result, the performance of the device is degraded.

### SUMMARY OF THE INVENTION

The purpose of the invention is to address the above problems. The verticality of the gate profile is improved, erosion of substrate at corner of the bottom is avoided, and therefore performance and reliability of the device is effectively improved.

To achieve the above purpose, the invention provides a method for manufacturing a semiconductor device, said method comprising:
forming a monocrystalline etch stop layer and a monocrystalline dummy gate layer on a substrate;
forming a dummy gate pattern by wet etching the dummy gate layer;
forming a gate spacer around said dummy gate pattern;
removing said dummy gate pattern by wet etching to form a gate trench; and
forming a gate stack in the gate trench.

Wherein, the etch stop layer and the dummy gate layer are formed by epitaxial growth.

Wherein, the etch stop layer applies stress to the substrate.

Wherein, said dummy gate layer includes monocrystalline Si and is wet etched with TMAH.

Wherein, sidewalls of said dummy gate pattern is formed of a crystal face (111).

Wherein after forming the dummy gate pattern, and before forming the gate spacer, the method further comprises forming lightly doped source and drain extension regions in the substrate on both sides of said dummy gate patter.

Wherein after forming the gate spacer and before wet etching the dummy gate layer, the method further comprises:
forming heavily doped source and drain regions in the substrate on both sides of the gate spacer;
forming an interlayer dielectric layer to cover the etch stop layer, the gate spacer and the dummy gate pattern; and
planarizing the interlayer dielectric layer to expose the dummy gate pattern.

Wherein, said etch stop layer includes monocrystalline SiGe, Si:C, Si:H, SiGe:C or their combinations.

Wherein, the gate spacer includes silicon nitride, silicon oxynitride, diamond like carbon or their combinations.

In the method for manufacturing a semiconductor device according to the invention, epitaxial monocrystalline thin film is used as the dummy gate and the stop layer for wet etching the dummy gate. As a result, the verticality of the gate profile is improved, erosion of substrate at corner of the bottom is avoided, and therefore performance and reliability of the device is effectively improved.

### BRIEF DESCRIPTION OF DRAWINGS

Detailed explanation of the technical solution in the invention is made with reference to the drawings, wherein:

FIGS. 1 to 7 are sectional views illustrating each step of the semiconductor device manufacturing method according to the invention, and

FIG. 8 is the flow chart of the semiconductor device manufacturing method according to the invention.

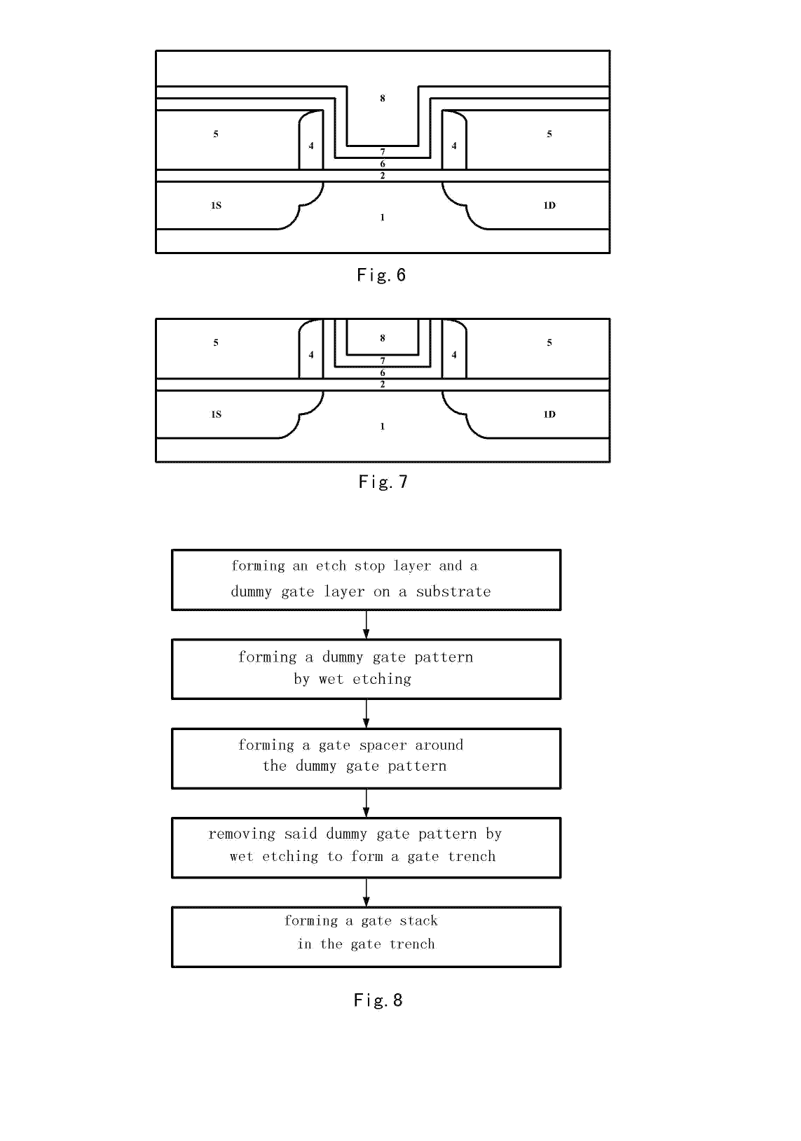

### DETAILED DESCRIPTION OF THE INVENTION

Detailed explanation of the features and technical effects of the technical solution in the invention is made with reference to the drawings, in conjunction with the exemplary embodiments below. It should be noted that similar references in the figures represent similar structure and the terms in this application “first”, “second”, “above” “below” “thick” and “thin” etc. can be applied to describe various structures of devices. These terms, unless stated otherwise, do not suggest any spatial, sequential or hierarchical relations.

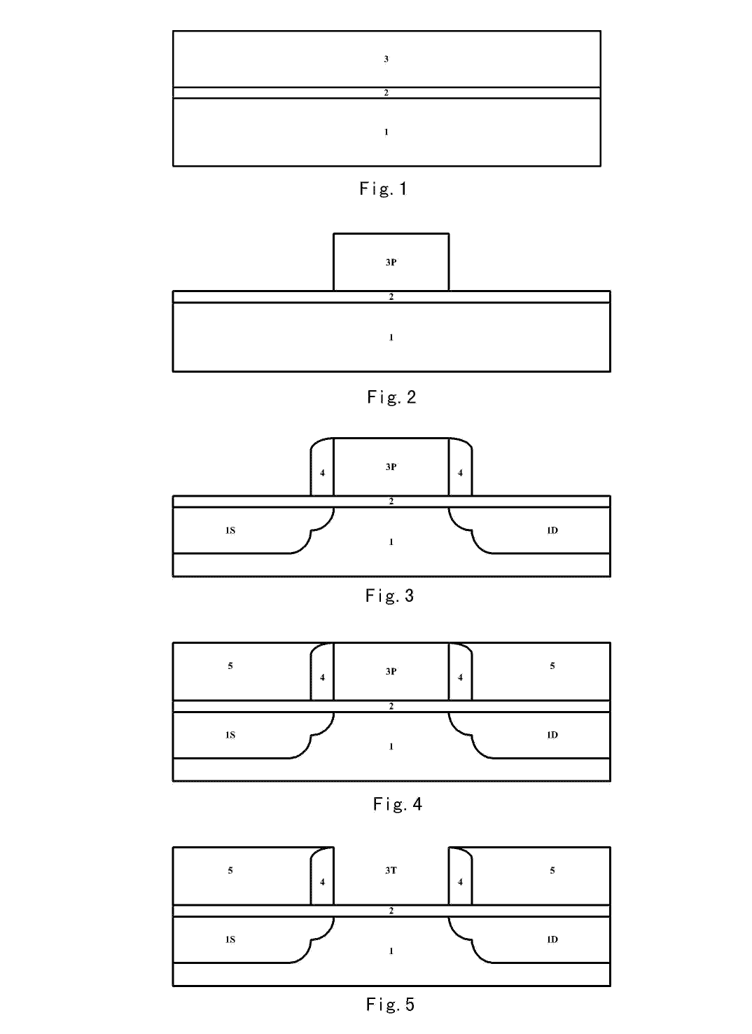

Refer to FIG. 1, an etch stop layer and a dummy gate layer are formed on a substrate. Substrate 1 including, for example, bulk Si, bulk Ge, GaAs, SiGe, GeSn, InP, InSb or GaN, is provided. Preferably, substrate 1 is bulk Si (for example, monocrystalline Si wafer). Substrate 1 has a first crystal face, for example, face (110). Thereafter, an etch stop layer 2 is epitaxially grown on the substrate 1, by PECVD, HDPCVD, MOCVD, MBE, ALD etc. The etch stop layer 2 may include, for example, SiGe, Si:C, Si:H, SiGe:C or their combinations. Preferably, the lattice constant of the material of the etch stop layer is approximate to that of the substrate 1, and preferably materials of both the etch stop layer and the substrate have at least one same element, such as Si. But they are different in chemical properties to improve the etching selection ratio, meanwhile to avoid increasing defects. Preferably, etch stop layer 2 includes a monocrystalline material, which helps to reduce interface defects and improve the reliability of the device. Specially, stress resulted from the difference of lattice constants between the etch stop layer 2 and the substrate 1 is applied to the substrate and the channel region, to increases the carrier mobility, thereby improving the performance of the device. Then, a dummy gate layer 3 is epitaxially deposited on the etch stop layer 2 by LPCVD, PECVD, HDPCVD, ALD, MBE and thermal decomposition, etc. The dummy gate layer 3 may include monocrystalline silicon, polysilicon, amorphous silicon, amorphous germanium, SiGe, Si:C or their combinations. And preferably, the material for the dummy gate 3 is the same as that for substrate 1 (for example, monocrystalline silicon), but different from that for the etch stop layer 2. Preferably, the dummy gate layer 3 is also made of monocrystalline material in order to reduce interface defects. Because layer 3 and layer 2 are both formed by epitaxial growth, defects therein are less compared to layers formed by common CVD or PVD. Thus, in the later etching process, a pattern with vertical sidewalls will be formed. Preferably, the crystal face of the dummy gate layer 3 is the same as that of the substrate 1, i.e. face (110).

Referring to FIG. 2, the dummy gate layer is wet etched, and the etching stops on the etch stop layer to form a dummy gate pattern. Photoresist is spinned on the dummy gate layer 3, exposed and developed to form a photoresist pattern (not shown), which is then used as a mask in the wet etching of the dummy gate layer 3 to form a dummy gate pattern 3P. For a Si dummy gate layer 3, TMAH is used. For dummy gate layer 3 made of materials other than Si, the combination of strong acid and strong oxidizer (for example, sulphuric acid and hydrogen peroxide) is used to the wet etching. Because etching rate for TMAH is comparatively low on face (111), the etching for forming pattern 3P will finally stop on the face (111). That is to say, the dummy gate pattern 3P has a second crystal face. Meanwhile, because TMAH hardly reacts with the etch stop layer 2 which is made of materials other than Si and some crystal faces (such as face (111)) in the family {111 } is vertical to the crystal face (110), the gate pattern 3P has vertical or nearly vertical sidewalls (e.g., the angle between the sidewalls and the bottom side is 90±0.5 degrees), with crystal face (111), gate lines are less rough and corner etching at bottom will not occur. Alternatively, a hard mask layer such as SiN (not shown) may be formed on the dummy gate layer 3. The hard mask layer is dry etched to form a pattern and then wet etching is performed. It should be noted that in order to utilize the stress of the etch stop layer to improve the carrier mobility, in the present embodiment, the etch stop layer is left after forming the dummy gate pattern 3P by etching. However, in other embodiments of the invention, after forming the dummy gate pattern 3P, the etching continues to remove the etch stop layer and expose the substrate.

Referring to FIG. 3, gate spacers are formed on the sidewalls of the dummy gate pattern 3P. An insulating dielectric layer is formed by a conventional process, such as LPCVD, PECVD, HDPCVD, magnetron sputtering etc. Examples of materials for the insulating dielectric layer include silicon nitride, silicon oxynitride, diamond like carbon (DLC) or their combinations. Gate spacers 4 are formed on the sidewalls by photolithography/etching. Preferably, the gate spacers 4 have stress to improve the carrier mobility in the channel region. It should be noticed that, in fact, during the processes as shown in FIGS. 2-3, source/drain regions IS/ID (including heavily doped regions and lightly doped source and drain extension regions) may be formed in the substrate 1 on both sides of the dummy gate pattern 3P. The method is well known and thus there is no need to repeat here.

Referring to FIG. 4, an interlayer dielectric layer 5 is formed on the device. The interlayer dielectric layer (ILD) 5 of a low-k material is formed by spinning, spraying, screen printing, CVD and so on. The material includes, but not limited to, organic low-k material (such as organic polymer containing aryl group or membered ring), inorganic low-k material (such as amorphous carbon nitride film, polycrystalline boron nitride film, fluorosilicate Glass, BSG, PSG, BPSG), porous low-k material (such as SSQ based porous low-k material, porous SiO₂, porous SiOCH, C doped SiO₂, F doped porous amorphous carbon, porous diamond, porous organic polymer). Preferably, silicon oxide is deposited by CVD to reduce the cost. Preferably, ILD 5 is planarized by CMP or etching back to expose the dummy gate pattern 3P.

Referring to FIG. 5, the dummy gate pattern 3P is removed by wet etching and a gate trench 3T is formed. Similar to the process shown in FIG. 2, the Si dummy gate pattern 3P is removed by wet etching with TMAH and the etching stops autonomously on the etch stop layer 2 made of materials other than Si. Because etching rate for TMAH is comparatively low on face (111) and the sidewalls of the dummy gate pattern 3P is face (111), the gate trench 3T has vertical or nearly vertical sidewalls (e.g., the angle between the sidewalls and the bottom side is 90±0.5 degrees). Because TMAH hardly reacts with the etch stop layer 2 made of materials other than Si and the defect density of the epitaxial layer is low, the gate trench 3T has vertical or nearly vertical sidewalls (e.g., the angle between the sidewalls and the bottom side is 90±0.5 degrees), gate lines are less rough and corner etching at bottom will not occur. For the similar reasons mentioned above, in order to utilize the stress of the etch stop layer to improve the carrier mobility, in the present embodiment, the etch stop layer is left after forming the dummy gate pattern 3P by etching. However, in other embodiments of the invention, after forming the dummy gate pattern 3P, the etching continues to remove the etch stop layer and exposure the substrate so as to form gate trench 3T.

Referring to FIG. 6, a gate insulating layer 6, work function adjusting layer 7, and resistance adjusting layer 8 are formed in the gate trench 3T and on ILD 5. A gate insulating layer 6 is deposited by PECVD, HDPCVD [symbol] MOCVD [symbol] MBE [symbol] ALD, etc. Examples of materials for forming the gate insulating layer 6 include silicon oxide, silicon nitride, silicon oxynitride, high-k material or their combinations. Wherein, high-k material includes, but not limited to, nitride (such as SiN, AN, TiN), metal oxide (mainly oxide of subgroup and lanthanide metal elements, such as Al₂O₃ [symbol] Ta₂O₅ [symbol] TiO₂ [symbol] ZnO [symbol] ZrO₂ [symbol] HfO₂ [symbol] CeO₂ [symbol] Y₂O₃ [symbol] La₂O₃), perovskite oxide (such as PbZrₓTi₁₋ₓO₃ (PZT) [symbol] BaₓSr₁₋ₓTiO₃ (BST). A work function adjusting layer 7 of Al, TiAl, TiN, or TaN is formed on the gate insulating layer 6 in the gate trench by MOCVD, MBE, ALD, evaporation and sputtering, etc. A resistance adjusting layer 8 of Cu [symbol] Al [symbol] Ti [symbol] Mo [symbol] Ta [symbol] W or their combinations is formed on the work function adjusting layer 7 by MOCVD, MBE, ALD, evaporation and sputtering etc.

Referring to FIG. 7, the gate insulating layer 6, work function adjusting layer 7 and resistance adjusting layer 8 is planarized to expose ILD 5, and thus the final gate stack structure 6/7/8 is formed. Thereafter, source and drain contact holes may be formed by etching in ILD 5 and filled with metals to form contacts. Finally, the wiring of the device is formed.

According to the method for manufacturing semiconductor devices, epitaxial monocrystalline films are used as a dummy gate and a stop layer for the wet etching of the dummy gate so that the verticality of the gate profile is improved, erosion of substrate at corner of the bottom is avoided, and therefore performance and reliability of the device is effectively improved.

The present invention has been described in the above in conjunction with one or more exemplary embodiments. However, those skilled in the art can make various replacement and modifications on the manufacturing methods of the device structure without departing from the scope of the present invention. Besides, based on the teaching of the present disclosure, various modifications can be made that might be suitable to special circumstances and materials without departing from the scope of this invention. Therefore, the purpose of the invention does not intend to limit to the special embodiments which are disclosed for realizing the best mode of the invention, while the disclosed device structure and its manufacturing method will cover all the embodiments falling within the scope of the invention.

1. A method for manufacturing a semiconductor device, comprising:
forming a monocrystalline etch stop layer and a monocrystalline dummy gate layer on a substrate;
forming a dummy gate pattern by wet etching the dummy gate layer;
forming a gate spacer around said dummy gate pattern;
removing said dummy gate pattern by wet etching to form a gate trench; and
forming a gate stack in the gate trench.

2. The method of claim 1, wherein the etch stop layer and the dummy gate layer are formed by epitaxial growth.

3. The method of claim 1, wherein the etch stop layer applies stress to the substrate.

4. The method of claim 1, wherein said dummy gate layer includes monocrystalline Si and is wet etched with TMAH.

5. The method of claim 1, wherein sidewalls of said dummy gate pattern is formed of a crystal face (111).

6. The method of claim 1, wherein after forming the dummy gate pattern and before forming the gate spacer, the method further comprises forming lightly doped source and drain extension regions in the substrate on both sides of said dummy gate pattern.

7. The method of claim 1, wherein after forming the gate spacer and before wet etching the dummy gate layer, the method further comprises:
forming heavily doped source and drain regions in the substrate on both sides of the gate spacer;
forming an interlayer dielectric layer to cover the etch stop layer, the gate spacer and the dummy gate pattern; and
planarizing the interlayer dielectric layer to expose the dummy gate pattern.

8. The method of claim 1, wherein said etch stop layer includes monocrystalline SiGe, Si:C, Si:H, SiGe:C or their combinations.

9. The method of claim 1, wherein the gate spacer includes silicon nitride, silicon oxynitride, diamond like carbon or their combinations.
